(19) United States
(12) Patent Application Publication
(10) Pub. No.: US 2006/0166381 A1
(43) Pub. Date: Jul. 27, 2006

(54) Mold cavity identification markings for IC packages

(76) Inventor: Bernhard P. Lange, Freising (DE)

Correspondence Address: TEXAS INSTRUMENTS INCORPORATED, P O BOX 655474, M/S 3999, DALLAS, TX, 75265, US

(21) Appl. No.: 11/215,539

(22) Filed: Aug. 30, 2005

Related U.S. Application Data
(60) Provisional application No. 60/647,160, filed on Jan. 26, 2005.

(51) Int. Cl. H01L 21/66

(52) U.S. Cl. 438/14

(57) ABSTRACT

The invention provides small-feature identifying markings for tracing completed IC packages to individual mold cavities. Preferred embodiments of the invention include IC packages and associated methods for forming indicia in a surface of an integrated circuit package in an arrangement indicative of a particular mold cavity. The indicia may be read to determine the particular mold cavity associated with the manufacture of an individual integrated circuit package. Preferred embodiments of the invention are included using surface dot or indentation indicia configured in a binary code arrangement.

### PRIORITY ENTITLEMENT

This application claims priority based on Provisional Patent Application 60/647,160, filed Jan. 26, 2005. This application and the aforementioned provisional application have a common inventor and are assigned to the same entity.

### TECHNICAL FIELD

The invention relates to the manufacture of integrated circuit assemblies, and more particularly, to methods for marking exterior surfaces of integrated circuit (IC) packages.

### BACKGROUND OF THE INVENTION

Electronic devices, also referred to generally as ICs (integrated circuits) encapsulated in plastic are produced and used in the electronics industry in large quantities. Following the complex processing involved in making an IC, encapsulation of the completed IC in plastic packaging is not only crucial to its use, but complex as well. Generally, the process involves bonding the IC die to a platform by gluing with a conductive material or by forming a eutectic bond with gold/silicon. The pads on the die are connected to leadfingers with very fine wires, for example aluminum or gold wires as small as 0.001 inch in diameter or smaller. The IC so prepared must then be protected and provided with an appropriate shape, strength, and identity.

Precision molds made of metal or other material are used for forming the package, usually in conjunction with presses and handling equipment for manipulating the ICs. The molds are complex and require much labor to produce. The molds have multiple cavities for producing numerous encapsulated devices during a single molding operation. Materials used for encapsulation include epoxy, silicone, and alkyd mold compounds. Commonly used methods of molding include compression molding, transfer molding and injection molding. Transfer molding is the predominant process, and epoxies and silicones are the main molding compounds used.

Regardless of the specific mold processes and materials used, it is sometimes desirable to trace a packaged device to the particular mold cavity used in its formation. Extensive assembly tools containing multiple molds are known, which can be used for example to encapsulate more than 100 individual ICs. Such molds must be built to extremely close tolerances to ensure accuracy in the final molded packages. Defects in completed IC packages are sometimes attributable to particular mold cavities, for example due to seepage causing excessive flashing or protuberances. Accordingly, mold cavity markings are often used to identify each individual mold cavity.

IC packages with very small dimensions and fragile components are susceptible to inadvertent damage in handling, packaging, and marking. Very small IC packages currently produced, such as “chip-scale” IC packages, have dimensions approximating those of a bare IC die itself and employ very minute external connection elements. This leaves little package space available to bear mold cavity markings. Current mold cavity tools known in the arts for IC package molding are designed to form readable alphanumeric character coding on each package. In the event of an assembly-related defect noted on a finished package, the alphanumeric identifier may be used to identify each individual molded package made using each particular mold cavity. The alphanumeric coding requires that the characters be made with sufficient depth and size to be readable. This requires a given amount of area, which lowers the available exposed die pad area on small packages, since the mold cavity marking is located on the bottom side of the package, as are the exposed die pads. Another problem is that the character embossing tools used to form alphanumeric markings can lift the relatively large exposed die pad of the leadframe, which can cause undesirable mold flashing to occur.

FIG. 1 (prior art) shows a package 10 representative of those made using an alphanumeric mold cavity coding tool known in the arts. The tool exerts pressure on the IC assembly to make the embossed characters 12 in the mold compound 14, and can also cause mold flashing and die cracking. Also notable is the relatively large area 16 required for the alphanumeric markings 12 in comparison with the area required for the exposed die pad 18. Due to these and other problems, there is a need in the arts for mold cavity marking which consumes less area, reduces the risk of damage to the IC, and nevertheless provides for reliable tracing of completed packaged ICs to their respective mold cavities.

### SUMMARY OF THE INVENTION

In carrying out the principles of the present invention, in accordance with preferred embodiments, the invention provides small-feature identifying markings for tracing completed IC packages to individual mold cavities.

According to one aspect of the invention, a preferred method includes steps for forming indicia in a surface of an integrated circuit package in an arrangement indicative of a particular mold cavity. The indicia may be read to determine the mold cavity associated with the manufacture of a particular integrated circuit package.

According to another aspect of the invention, the steps include forming a number of indicia in a binary code arrangement.

According to yet another aspect of the invention, a method of the invention further includes steps for forming indicia using textured dots in the surface of the integrated circuit package.

According to still another aspect of the invention, an alternative method of the invention further includes steps for forming indicia using indentations in the integrated circuit package.

According to another aspect of the invention, an integrated circuit package includes a semiconductor die encapsulated in mold compound and a number of indicia positioned in the surface of mold compound for identifying a mold cavity associated with the manufacture of the IC package.

According to aspects of preferred embodiments of the invention, mold cavity indicia in a packaged IC may be located on the bottom, top, or side of the package.

According to another aspect of the invention, mold cavity indicia in a packaged IC may be located between package leads.

The invention has advantages including but not limited to improved methods for making identifying marks on IC packages using reduced area, reduced depth, less risk of damage to the IC, and more flexibility in mark location. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 (prior art) is a bottom view representative of an example of an integrated circuit package with alphanumeric coding according to the prior art;

FIG. 2 is a bottom view of an integrated circuit package with mold cavity coding according to an example of a preferred embodiment of the invention;

FIG. 3 is a cut-away side view of the preferred embodiment of the invention shown in FIG. 2;

FIG. 4 is a bottom view of an integrated circuit package with binary coding according to an alternative example of a preferred embodiment of the invention;

FIG. 5 is a side view of the preferred embodiment of the invention shown in FIG. 4; and

FIG. 6 is a bottom view of an integrated circuit package with mold cavity identification coding according to another alternative embodiment of the invention.

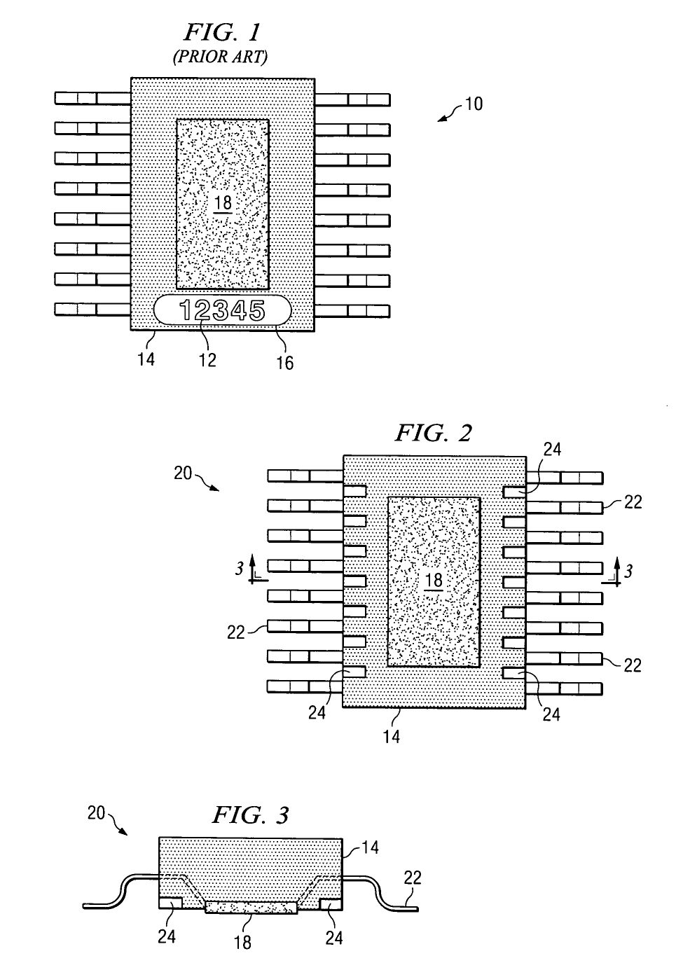

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DESCRIPTION OF PREFERRED EMBODIMENTS

In general, the invention provides indicia on one or more surface or edge of an IC package for encoding the identity of the mold cavity used in the manufacture of the particular package. The indicia are preferably optically readable and may be arranged in a binary code scheme. The indicia themselves are referred to herein as “dots” and “indentations” to differentiate between preferred embodiments using surface indicia and deeper indicia. It should be understood that the indicia used in implementing the invention may take various forms of indentation, dot, spot, groove, trench, divot, niche, ridge, bump, or other readable mark without departing from the scope of the invention, and that the indicia may be used on the top, bottom, side, or edge of a package.

Now referring primarily to FIG. 2, an exemplary embodiment of a package 20 made according to the invention is shown in a bottom view. As shown, leads 22 extend from die area, indicated by die pad 18, as is common in the arts. The mold cavity markings are recorded using indicia 24 formed in the mold compound. The indicia shown in this example in the form of indentations are molded or etched into the long side of the package 20 between the leads 22. Many alternatives exist for the size, shape and location of indicia within the scope of the invention. Although fourteen identical indicia 24 are shown in FIG. 2 for the purpose of illustrating an exemplary indicia location pattern for use with the invention, it should be understood that in practice it is not usual for all indicia 24 to indicate the same value. The “encoding” of the indicia 24 may be varied as necessary in order to signify particular mold cavity locations as needed in the particular application. More or fewer than fourteen indicia 24 may also be used. For example, the invention may be used wherein a filled indicium indentation is read as a “0” and an open indicium is read as a “1”, or vice versa. The encoded values indicative of mold location may be read in a direction consistent with the numbering of the package leads, although other approaches may be used. Preferably, binary codes may be used to indicate a unique identifier for each mold cavity location in use in a particular mold. FIG. 3 is a cut-away side view of the package 20 of FIG. 2 taken along line 3-3. Two open indicia 24 are shown.

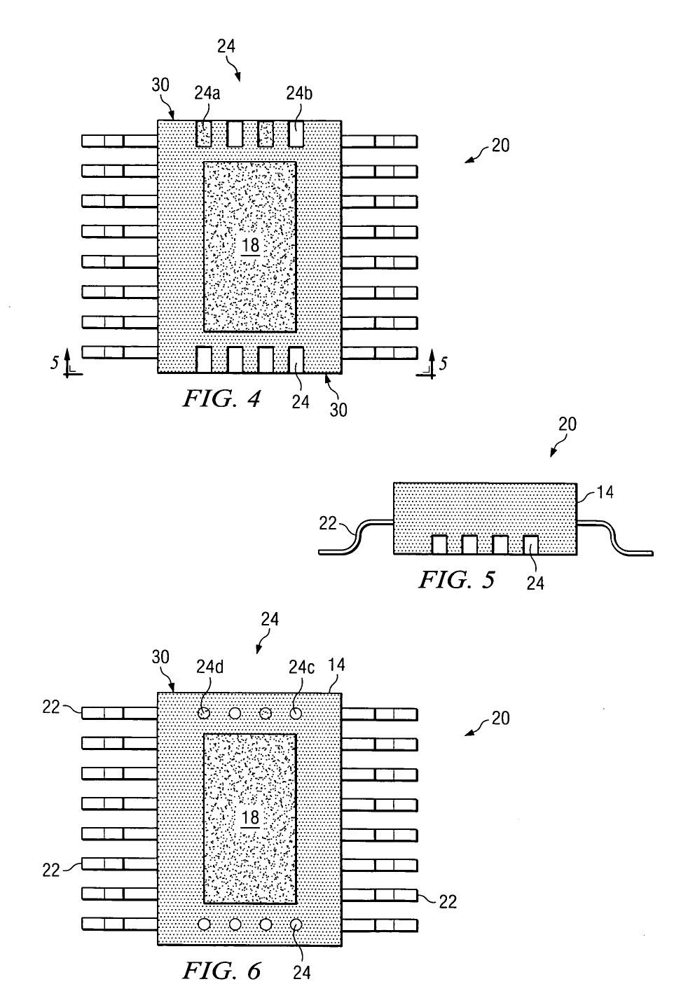

As shown in the alternative embodiment depicted in FIG. 4, the mold cavity coding indicia 24 may also be formed in the small package side 30. As mentioned with respect to FIG. 3, a binary coding scheme may be used as needed to indicate a particular mold cavity. Eight indicia 24 are shown for the sake of example in this alternative embodiment. At the top of FIG. 4, two filled 24a and two unfilled indicia 24b are shown, which may be used to represent the binary values “one” and “zero”. Thus, (assuming a starting point at the upper left-hand corner) the embodiment of FIG. 4 could read “1010000”, or “01011111”, for example, or some other value, depending upon the encoding scheme and starting point selected for implementing the invention. Another view of this alternative embodiment is shown in FIG. 5. In the side view of FIG. 5, it may be appreciated that the indicia 24 may be arranged so as to be readable from the edge of the package 20 in addition to or instead of only from the bottom. Of course, those skilled in the arts will also recognize that the indicia may be placed on top of the package as well without departure from the scope of the invention.

Now referring primarily to FIG. 6, the invention may alternatively be embodied using indicia 24 formed on a surface of the package 20 as shown. For example, “shiny” circular or “dot” indicia 24c, e.g. “ones”, may be formed by not roughening the mold used to form the package at the selected location, and the “matt” indicia 24d, e.g. “zeros”, may be used to identify the indicator 24d location, or may be omitted entirely. As with the other embodiments shown and described herein, the indicia 24 may also be placed also on the long side of the package, between the leads 22, or on an “edge,” “side” or “top” surface. Of course, the use of eight indicia as shown by way of example is not intended to imply limitations or restrictions on the number or arrangement of indicia used in the practice of the invention.

The invention provides advantages including but not limited to reductions in the area and depth of mold cavity identification markings for IC packages. Additional advantages may be realized in terms of cost, flexibility in the location of the markings, and including an increased amount of information in the markings. While the invention has been described with reference to certain illustrative embodiments, those described herein are not intended to be construed in a limiting sense. It will be appreciated by those skilled in the arts that the invention may be used with various types of semiconductor devices and package types. For example, the code marking of the invention may be placed on the top or sides of packages as well as on the bottom surface using binary or other coding schemes. Various modifications and combinations of the illustrative embodiments as well as other advantages and embodiments of the invention will be apparent to persons skilled in the arts upon reference to the drawings, description, and claims.

I claim:

1. An integrated circuit package marking method comprising the steps of:
forming a plurality of indicia on a surface of an integrated circuit package, the indicia placed in an arrangement indicative of a particular mold cavity;
reading the plurality of indicia on the integrated circuit package to determine the mold cavity associated with the particular integrated circuit package.

2. A method according to claim 1 further comprising the step of forming the plurality of indicia in a binary code arrangement.

3. A method according to claim 1 wherein the step of forming indicia further comprises forming a plurality of indentations in the integrated circuit package.

4. A method according to claim 1 wherein the step of forming indicia further comprises forming a plurality of textured dots in the surface of integrated circuit package.

5. A method according to claim 1 further comprising the step of forming the plurality of indicia on the bottom of the package.

6. A method according to claim 1 further comprising the step of forming the plurality of indicia between package leads.

7. A method according to claim 1 further comprising the step of forming the plurality of indicia on the top of the package.

8. A method according to claim 1 further comprising the step of forming the plurality of indicia on a side of the package.

9. A method according to claim 1 further comprising the step of forming the plurality of indicia on an edge of the package.

10. An integrated circuit package comprising:
a semiconductor die encapsulated in mold compound;
a plurality of indicia indentations in a surface of the mold compound, the indicia disposed in an arrangement indicative of a particular mold cavity.

11. An integrated circuit package according to claim 10 wherein the indicia are disposed in a binary code arrangement.

12. An Integrated circuit package according to claim 10 wherein the plurality of indicia are located on the bottom of the package.

13. An Integrated circuit package according to claim 10 wherein the plurality of indicia are located between package leads.

14. An Integrated circuit package according to claim 10 wherein the plurality of indicia are located on the top of the package.

15. An Integrated circuit package according to claim 10 wherein the plurality of indicia are located on a side of the package.

16. An Integrated circuit package according to claim 10 wherein the plurality of indicia are located on an edge of the package.

17. An integrated circuit package comprising:
a semiconductor die encapsulated in mold compound;
a plurality of surface dot indicia in a surface of the mold compound, the indicia disposed in an arrangement indicative of a particular mold cavity.

18. An integrated circuit package according to claim 17 wherein the indicia are disposed in a binary code arrangement.

19. An Integrated circuit package according to claim 17 wherein the plurality of indicia are located on the bottom of the package.

20. An Integrated circuit package according to claim 17 wherein the plurality of indicia are located between package leads.

21. An Integrated circuit package according to claim 17 wherein the plurality of indicia are located on the top of the package.

22. An Integrated circuit package according to claim 17 wherein the plurality of indicia are located on a side of the package.

23. An Integrated circuit package according to claim 17 wherein the plurality of indicia are located on the edge of the package.
